(19) United States
(12) Patent Application Publication
(10) Pub. No.: US 2023/0075019 A1
(43) Pub. Date: Mar. 9, 2023

(54) ELECTRONIC SYSTEM WITH POWER DISTRIBUTION NETWORK INCLUDING CAPACITOR COUPLED TO COMPONENT PADS

(71) Applicant: Smoltek AB, GÖTEBORG (SE)

(72) Inventors: M Shafiqul Kabir, VÄSTRA FRÖLUNDA (SE); Vincent Desmaris, GÖTEBORG (SE); Anders Johansson, ÖCKERÖ (SE); Ola Tiverman, VÄSTRA FRÖLUNDA (SE); Karl Lundahl, GÖTEBORG (SE); Rickard Andersson, GÖTEBORG (SE); Muhammad Amin Saleem, GÖTEBORG (SE); Maria Bylund, GÖTEBORG (SE); Victor Marknäs, MÖLNDAL (SE)

(21) Appl. No.: 17/795,999

(22) PCT Filed: Jan. 28, 2021
(86) PCT No.: PCT/SE2021/050053

§ 371 Date: Jul. 28, 2022

(30) Foreign Application Priority Data
Feb. 6, 2020 (SE) 2050123-5
Feb. 6, 2020 (SE) 2050124-3
Feb. 6, 2020 (SE) 2050125-0

(51) Int. Cl. H01L 25/16; H05K 1/11; H01G 4/005; H01L 49/02; H01L 23/00; H01L 23/64; H05K 1/02

(52) U.S. Cl. CPC H01L 25/16; H05K 1/111; H01G 4/005; H01L 28/90; H01L 28/84; H01L 24/16; H01L 23/642; H05K 1/0231; H05K 2201/10015; H01L 2224/16225; H01L 2924/15331; H01L 2924/19041; H01L 2924/19106; H01L 2924/19103; H01L 23/49816

(57) ABSTRACT

An electronic system comprising a substrate with a substrate conductor pattern including substrate pads; a semiconductor component with active circuitry, and component pads coupled to the active circuitry of the semiconductor component and connected to the substrate pads of the substrate; a power source interface for receiving power from a power source; and a power distribution network for distributing power from the power source interface to the active circuitry of the semiconductor component. The power distribution network includes a first capacitor realized by conductive structures comprised in the semiconductor component, the first capacitor being coupled to a first component pad and a second component pad of the semiconductor component; a second capacitor arranged between the substrate and the semiconductor component, the second capacitor being coupled to the first component pad and the second component pad of the component package; and a power grid portion of the substrate conductor pattern.

### FIELD OF THE INVENTION

The present invention relates to an electronic system comprising a power distribution network (PDN).

### BACKGROUND OF THE INVENTION

As a path forward beyond Moore's law, 2.5D and 3D integrations of the next generation silicon technology has emerged. Such schemes provide continuing system scaling at SoC/SiP level, performance enhancement, higher frequency operations, overall reduction of power consumption, device miniaturization, and cost minimization. Moreover, 2.5D/3D technology is also driving faster time to market for new system applications ranging from low-end portable electronics to high end super computers. Hence 2.5D and 3D silicon die stacking and silicon packaging integration drive the development of the entire semiconductor industry. Such integrations however are generating other issues such as power management to provide power to those silicon dies when and where needed at a given frequency, thermal management etc. To manage the power demand and distribution in a system, a power distribution/delivery network (PDN) is used. The role of the PDN is to deliver a stable power supply from the power source, often referred to as voltage regulator module (VRM), to all components in the system.

At the die level, in a CMOS circuit, a logic die draws current when its transistors are switching, leading to a ripple voltage in the PDN. This effect is known as simultaneous switching noise (SSN) and considered to be the main source of noise in a digital IC. Since at the circuit level, the high and low logic states are defined by sensing the voltage (with an acceptance margin), voltage ripple in the PDN exceeding this margin can lead to logical errors in the core process. With the advancement of transistor technology, today's transistor can switch at much higher frequencies, more frequently resulting in SSN noise to appear.

To maintain the course of increased performance, traditional architectures of microelectronic devices are evolving towards a 3D integrated circuit architecture (3DIC), where heterogeneous dies are stacked on top of each other. While, full 3D stacking solutions wait for the evolution of the whole industry ecosystem, 2.5D has emerged as an intermediate step in terms of design and process maturity where silicon dies are positioned side by side or in the form of so-called chiplets for integration on an interposer e.g. silicon or glass. An interposer with a higher density of interconnects, allows several heterogeneous dies to be stacked on its surfaces, thereby increasing their communication bandwidth. However, the addition of the interposer brings complexity to the overall packaging structure by introducing new elements such as TSVs, μ-bumps, front-side and back-side redistribution layers (RDL) that act as parasitic elements in the PDN of the system.

It is well known for a classical circuit that a major issue in power management comes from chip/package anti-resonance taking place when a parallel LC resonator circuit is formed between on-chip capacitance C_{FE} and package inductance. Such problems become even more prominent for 2.5D/3D packaging. The complexity induced by stacking dies generates several noticeable effects on PDN's quality. If multiple logic dies are integrated on the same platform, the current drawn by transistors during switching is increased, resulting in higher SSN. The new elements present in the interposer structures promote higher impedance peaks at intermediate frequencies.

Miniaturization is not happening only at the die or packaging level. Increasing demand from end-users for thinner/compact but more functional smartphones for example, requires a constant reduction in the area of the logic board which accommodates all the components.

Such a reduction in board area would, for instance, allow implementing a larger battery.

However, a printed circuit board (PCB) or substrate like PCB (SLP) is subjected to both power and return plane bounce developed in PDN when digital components transition logic states. State changes cause significant current spikes in the power and return rails at every edge time and are sometimes called “ground bounce” or “shoot-through” potentials. If there is insufficient energy storage for either the power and return pins, plane bounce will occur.

Both power and return planes in a PCB/SLP are treated as transmission lines and the planes must be terminated in their characteristic impedance. When a component switches states, a propagating wave effect occurs, traveling to the edge of the PCB/SLP and reflecting back. With multiple switching frequencies, phase addition/subtraction will occur somewhere within the PDN. If the additive value of ringing exceeds the threshold level of a component's power/return pins, functional problems may occur. Two reasons are known responsible for plane bounce: (a) from lack of energy storage from decoupling capacitors or buried capacitance, and (b) from reflective wave switching interacting with “holes” in the layout that “cannot” be removed by capacitive structures. Moreover, the impedance of the power/return plane pair varies throughout the frequency spectrum. In a complex system as e.g. a smartphone/computer, there are always multiple components switching logic states simultaneously. If plane bounce exceeds voltage margin levels, digital components may cease to function properly.

At PCB/SLP level, when a component is in direct connection with a capacitor at a specific x/y axis position, the position may create a low impedance. When a component is not decoupled by capacitor(s) due to distance spacing between the device(s) and capacitor(s), it can be subjected to large plane bounce and can be aggravated by the holes of the via anti-pads. This large plane bounce is caused by phase addition of multiple propagating waves reflecting back from the board edges and from through-hole via disruptions in the z-axis direction of the PCB/SLP assembly. Therefore, the power distribution network (PDN), namely power and return planes, must provide sufficient energy charge during edge transitions. A functional PCB used in a gadget may have hundreds or even thousands of switching elements, which makes it even more important to tackle the issues of plane bounce in such a PDN.

The overall structural complexity of state-of-the-art logic boards, requires an increased control over PDN impedance. To tackle this problem, a method widely used by circuit designer to ensure PDN reliability is the definition of target impedance Z_{TARGET}. The power network impedance response must remain under this value over the whole operating frequency range where current transient exists. The Z_{TARGET} value is defined by:

Z_{TARGET}=V_{dd}α/(Iₘₐₓ−Iₘᵢₙ)

where V_{dd} represents the logic core voltage, α is the allowed ripple voltage ratio, Iₘₐₓ the maximum current flowing in the circuit and Iₘᵢₙ the minimum current during idle state. The transient current in the circuit is the difference between Iₘₐₓ and Iₘᵢₙ. Z_{TARGET} is expected to decrease with the development in IC technology, from a typical value of 0.5 Ohm for the 22 nm technology node to 0.38 Ohm for the 10 nm technology node, with the trend being a further reduction in the target impedance.

A careful PDN design and choice of conducting materials can reduce the inductances in the PDN to a certain limit defined by the intrinsic impedances of the materials forming the interconnections. To further improve the PDN functionality, capacitors are used. In a PDN, decoupling capacitors act as local energy storages providing electrons to the switching transistors, which is essential for reducing high transient current noise and to provide a low impedance power delivery path. Furthermore, the power supply may suffer from the parasitic impedance of the interconnections in the circuit loop inducing anti-resonance effects. Therefore, a proper distribution of those various energy storing capacitors in the PDN allows the PDN designer to mitigate antiresonance peaks in order to keep PDN impedance under Z_{TARGET} over the whole operating frequency range of the device.

Thus, decoupling capacitors are widely used in high performance power distribution systems today, supplying the peak current needs for rapidly switching circuits, reducing electromagnetic interference (EMI), providing an AC path between the power rail and ground rail for return currents, and lowering the total impedance of power distribution networks. Decoupling performance is, however, driven by the capacitor value and its access impedance as seen by the logic, which depends on, inter alia, its position in the PDN.

Different values of capacitors need to be distributed throughout different circuit floorplans due to varying sizes, bandwidth of operations, effective functional reach, and associated costs. The most commonly used decoupling capacitors are found in discrete component format, Surface Mountable Devices (SMD) capacitors and are typically placed on PCB due to the bulky size of these capacitors. Capacitors with intermediary sizes are used for interposer floor planning in the form of, for example, trench silicon capacitors (TSC). The on-chip capacitors (C_{FE}) are located in the transistor planes of the logic die (front-end) and/or between the on-chip different interconnect metal layers.

Implementation of different types of decoupling capacitors support the PDN at different frequency ranges. For example, C_{PCB} allow the introduction of large capacitance values, but their high access impedance/loop inductance (up to several nH) compared to on-chip decoupling capacitor method limits their response to lower frequencies (˜100 MHz). On the other hand, C_{FE} exhibits limited capacitance values with very low access impedance allowing the decoupling of higher frequencies (>2 GHz). However, the on-chip NMOS decoupling capacitors have limited capacitance (≤0.1 μF) due to a lack of the area of a chip.

The interconnects network that brings power from the source to the die pads creates loop inductance. This loop inductance may cause a voltage drop (ΔV) across the PDN, that will be experienced by the die pads. Such voltage drop (ΔV) becomes a prominent issue where the operating voltage has been reduced to below 1.8 Volts and is steadily downscaling. At such operating voltages, the voltage drop caused by the loop inductance can be high enough to affect the on/off function of the electrical devices (e.g. transistors) connected to the die pads. The problem of loop inductance also becomes worse with increasing clock frequency, which decreases the duration of the on/off state of a device. The relationship between the ΔV and the inductance (L) is expressed by ΔV=Ldl/dt, where Voltage drop (ΔV) is equivalent to inductance (L) multiplied by current increase or decrease rate dl/dt. As mentioned earlier, the higher the clock frequency the higher the dl/dt. On the other hand, lower operating voltages for the advanced devices pushes the acceptable ΔV to be even lower. Therefore, the total loop inductance including any parasitics must be minimized for the ΔV to be within an acceptable range.

To solve the PDN problems at die level by increasing on-chip capacitance however leads to a prohibitive increase in the size, thus the cost of logic dies. Such a method is disclosed in US 2017/0069601, where the on-chip capacitors are used in a die for providing enhanced on-chip decoupling capacitance for power management of a memory die. The method also involves expensive through-silicon vias (TSVs) to be present in each die which is cost prohibitive. US 2017/0012029 describes that a MIM capacitor structure is formed at the back side of a die. Such a scheme, however, needs to be CMOS compatible and must be done on every die that is to be assembled.

Adding on-package decoupling capacitors has so far been found to be reasonably effective to limit anti-resonance at intermediate frequencies. Advantages of having an integrated silicon-based capacitor on an interposer are explained in U.S. Pat. No. 7,518,881. U.S. Pat. No. 7,488,624 describes how to configure multiples of silicon based integrated capacitors in an interposer. Yet another example of an integrated capacitor is disclosed in U.S. Pat. No. 8,618,651, where silicon capacitors are formed within blind TSV vias. Another examples of silicon trench-based capacitor are disclosed in U.S. Pat. Nos. 9,236,442 and 9,257,383, where high aspect ratio silicon trenches are used to manufacture capacitor devices.

Hence, traditional silicon based embedded high aspect ratio trench capacitor technology has matured to be used for volume production and may be found in today's smartphone packaging. However, given the trend in miniaturization, the potential of the silicon-based capacitor technology is limited by the ability to tailor the capacitor density per unit area, as well as by undesired parasitic resistances, increased film stress in the silicon substrate during processing, escalated manufacturing complexity and economy of costs per functions.

MLCC on the other hand, is the most prominent type of discrete capacitor component used in the world. Trillions of such discrete components are used every year. Today's industry standard MLCC/TSC/LICC capacitor technologies to manufacture such discrete components are challenged to comply with the increasing demand for lower height (Z height) to be sub 100 μm and preferably below 20 μm. This demand is due to the fact that the ICs that are integrated in packaging SoC/SiP packaging require sub 50 μm height of the capacitor to accommodate between the SoC/SiP packaging solutions due to decrease in the bumps interconnects heights and pitch/spacing. Further miniaturization of these components based on those established technologies thus may not be as cost competitive as it was before. It is particularly challenging to match with the need to be small enough both in 2D and in 3D space such that the discrete capacitor components can fit between the flip chip bumps interconnects without compromising the cost.

Accordingly, despite the technological advancements in the development of integrated capacitors, as well as discrete capacitors, there is currently no capacitor technology capable of accommodating the full requirements and needs of PDN configurations for future high packaging density and high performance electronic devices.

It would therefore be desirable to provide an improved electronic system, providing for improved power distribution.

### SUMMARY

In view of the above, it is an object of the present invention to provide an improved electronic system, providing for improved power distribution.

According to a first aspect of the present invention, it is therefore provided an electronic system comprising: a substrate with a substrate conductor pattern, the substrate having substrate pads included in the substrate conductor pattern; a semiconductor component with active circuitry, and component pads coupled to the active circuitry of the semiconductor component, the component pads being connected to the substrate pads of the substrate; a power source interface for receiving power from a power source, the power source interface being connected to the substrate conductor pattern; and a power distribution network for distributing power from the power source interface to the active circuitry of the semiconductor component, the power distribution network including: a first capacitor realized by conductive structures comprised in the semiconductor component, the first capacitor being coupled to a first component pad and a second component pad of the semiconductor component; a second capacitor arranged between the substrate and the semiconductor component, the second capacitor being coupled to the first component pad and the second component pad of the component package; and a power grid portion of the substrate conductor pattern.

The electronic system may be any electronic system providing functionality in an electronic device or in other equipment or machinery including one or several electronic systems. An example of an electronic system may be a logic board in a mobile phone, or a computer, or a vehicle, etc.

The substrate may advantageously be a multi-layer substrate, in which the conductor pattern includes several layers of conductive structures that are separated by dielectric layers. Examples of suitable substrates may include printed circuit boards (PCBs), substrate-like PCBs (SLPs), glass, LTCC (low temperature co-fired ceramic) or silicon-based substrates.

The power interface maybe configured to receive power from various power sources, including for example a VRM, a battery, a low drop-out linear regulator (LDOs), a DC-DC converter, an SMPS, a PMU, a PMIC, a power IC, or a combination thereof, or any other types of power sources used in the industry at different stages of the PDN.

The semiconductor component may be in the form of a so-called naked die semiconductor component, or the semiconductor component may include one or several integrated circuit dies bonded to a carrier. Such integrated circuit dies may, for example, be stand-alone ICs or a collection of so-called chiplets together providing the desired functionality. In embodiments, the semiconductor component may include a so-called interposer. Depending on the application, the semiconductor component may or may not be embedded in a dielectric encapsulation material. Of course, the electronic system may advantageously include several semiconductor components mounted on the substrate and connected to substrate pads. Semiconductor components may be arranged on one side of the substrate or both sides if the substrate.

The conductive structures realizing the first capacitor may be conductive structures, such as metal layers, of one or several semiconductor integrated circuit dies. Alternatively, or in combination, conductive structures realizing the first capacitor may be formed on a surface of one or several semiconductor integrated circuit dies using post processing techniques.

The present aspect of the invention is based upon the realization that the desired improved power distribution in the electronic system can be achieved by providing, as part of the PDN or the electronic system, a first capacitor realized by conductive structures comprised in the semiconductor component and coupled to a pair of component pads, and a second capacitor arranged between the substrate and the semiconductor component and coupled to the same pair of component pads.

In particular, this arrangement the second capacitor may reduce the length of the conductive path between the first capacitor and the second capacitor, which, in turn, reduces the inductance in that part of the PDN. Furthermore, valuable substrate surface space may be made available, allowing for a more compact electronic system.

Advantageously, the second capacitor may be a discrete capacitor component having a first connecting structure bonded to the first component pad and a second connecting structure bonded to the second component pad.

The second capacitor may advantageously be a discrete nano-structure based capacitor, comprising: at least a first plurality of electrically conductive nanostructures; a dielectric material embedding each nanostructure in the first plurality of conductive nanostructures; a first electrode conductively connected to each nanostructure in the first plurality of nanostructures; a second electrode separated from each nanostructure in the first plurality of nanostructures by the dielectric material, a first connecting structure conductively connected to the first electrode, the first connecting structure being bonded to the first component pad; and a second connecting structure conductively connected to the second electrode, the second connecting structure being bonded to the second component pad.

Further improved power distribution in the electronic system can be achieved through the inclusion in the power distribution network of discrete nano-structure based capacitors providing improved properties, including one or several of a higher capacitance per unit area, a lower component height, a reduced equivalent series inductance (ESL), a capacitance value that is not reduced when a DC-bias is applied across the capacitor, etc.

According to various embodiments, the conductive nanostructures in the first plurality of conductive nanostructures may be vertical nanostructures grown from the first electrode layer. The use of grown nanostructures allows extensive tailoring of the properties of the nanostructures. For instance, the growth conditions may be selected to achieve a morphology giving a large surface area of each nanostructure, which may in turn increase the energy storage capacity of the nanostructure energy storage device. Moreover, the growth conditions may be selected to achieve a desired self-resonance frequency (SRF) of the nanostructure-based capacitor component.

The nanostructures may be selected from one of nanowire, nano-horns, nanotube, nano-walls, crystalline nanostructures, or amorphous nanostructures.

The nanostructures may advantageously be carbon nanostructures, such as carbon nanofibers, carbon nanotubes or carbide-derived carbon nanostructures.

According to embodiments, the dielectric material may advantageously be arranged as a conformal coating on each nanostructure in the first plurality of conductive nanostructures.

According to embodiments, the second electrode may cover the dielectric material.

According to various embodiments, moreover, the nanostructure energy storage device may further comprise a second plurality of conductive nanostructures embedded in the dielectric material.

In such embodiments, the second electrode may be conductively connected to each nanostructure in the second plurality of nanostructures.

In some embodiments, each nanostructure in the second plurality of conductive nanostructures may advantageously be grown from the second electrode.

The second electrode, or a portion of the second electrode, may instead be connected to the tip of nanostructures in the second plurality of nanostructures. In such embodiments, the nanostructures may be grown, embedded in the dielectric material, and the tips of the nanostructures then be exposed by removal of dielectric material, for example through dry or wet etching or polishing.

According to further embodiments, the first electrode, or a portion of the first electrode, may also be connected to the tip of nanostructures in the first plurality of nanostructures. In such embodiments, the nanostructures may be grown, embedded in the dielectric material, and the tips of the nanostructures then be exposed by removal of dielectric material, for example through dry or wet etching or polishing. Accordingly, both the first electrode and the second electrode may be provided after growth of the nanostructures.

The dielectric material in the nano-structure based capacitor(s) provides for energy storage by preventing electrical conduction from the conductive nanostructures in the first plurality of nanostructures to the second electrode. Hereby, energy can be stored through accumulation of charge at the nanostructure—dielectric interface. The dielectric may advantageously be a so-called high-k dielectric. The high k-dielectric materials e.g. be HfOx, TiOx, TaOx, NiOx, MoOx, CuOx or other well-known high k dielectrics. Alternatively, the dielectric can be polymer based e.g. polypropylene, polystyrene, poly(p-xylylene), parylene etc. Other well-known dielectric materials, such as SiOx or SiNx, etc may also be used. The dielectric material or materials maybe deposited via CVD, thermal processes, ALD or spin coating or spray coating or any other suitable method used in the industry.

In embodiments, the first capacitor may have a capacitance less than 100 nF; and the second capacitor may be a discrete capacitor component having a component thickness being less than 100 μm, and a capacitance per component footprint area of more than 1000 nF/mm².

Through this combination of properties, the electrical design/impedance optimization of the PDN may be facilitated. The exceptionally small component thickness enables arrangement of the second capacitor between the substrate and the semiconductor component even with state-of-the-art, low-profile bonding solutions for bonding the semiconductor component to the substrate. Furthermore, the outstanding capacitance density enables the provision of a second capacitor having a high capacitance value while still physically fitting between first and second component pads.

According to embodiments, the power distribution network may further comprise a set of capacitors bonded to the power grid portion of the substrate conductor pattern.

At least one capacitor in the set of capacitors bonded to the power grid portion of the substrate conductor pattern may advantageously exhibit an equivalent series inductance of less than 100 pH for every frequency within a frequency range between the self-resonance frequency (SRF) and 1000 times the SRF of the capacitor.

Each capacitor in the set of capacitors bonded to the power grid portion of the substrate conductor pattern may advantageously exhibit an unchanged or increased capacitance when subjected to a DC voltage bias, as compared to its capacitance in an unbiased state.

Each capacitor in the set of capacitors bonded to the power grid portion of the substrate conductor pattern may advantageously be a nano-structure based capacitor, comprising: at least a first plurality of electrically conductive nanostructures; a dielectric material embedding each nanostructure in the first plurality of conductive nanostructures; a first electrode conductively connected to each nanostructure in the first plurality of nanostructures; a second electrode separated from each nanostructure in the first plurality of nanostructures by the dielectric material, a first connecting structure conductively connected to the first electrode, the first connecting structure being bonded to the power grid portion of the substrate conductor pattern; and a second connecting structure conductively connected to the second electrode, the second connecting structure being bonded to the power grid portion of the substrate conductor pattern.

According to a second aspect of the present invention, it is provided an electronic system comprising: a substrate with a substrate conductor pattern and substrate pads included in the substrate conductor pattern; a semiconductor component with active circuitry, and component pads coupled to the active circuitry, the component pads being connected to the substrate pads; a power source interface for receiving power from a power source, the power source interface being connected to the substrate conductor pattern; and a power distribution network for distributing power from the power source interface to the active circuitry of the semiconductor component, the power distribution network including: a power grid portion of the substrate conductor pattern; a first set of capacitors bonded to the power grid portion of the substrate conductor pattern; and a second set of capacitors integrated in the semiconductor component, wherein each capacitor in the first set of capacitors is a discrete nano-structure based capacitor, comprising: at least a first plurality of electrically conductive nanostructures; a dielectric material embedding each nanostructure in the first plurality of conductive nanostructures; a first electrode conductively connected to each nanostructure in the first plurality of nanostructures; a second electrode separated from each nanostructure in the first plurality of nanostructures by the dielectric material, a first connecting structure conductively connected to the first electrode, the first connecting structure being bonded to the power grid portion of the substrate conductor pattern; and a second connecting structure conductively connected to the second electrode, the second connecting structure being bonded to the power grid portion of the substrate conductor pattern.

The first set of capacitors bonded to the power grid portion of the substrate conductor pattern may include at least one discrete capacitor component. It should be understood that a “discrete” component is a stand-alone component that may be attached to a carrier and conductively connected to a conductor pattern on the carrier, as opposed to being formed in a step-by-step process on the carrier.

The second set of capacitors integrated in the semiconductor component may be one or more capacitors formed using conductive structures, such as metal layers, of one or several semiconductor integrated circuit dies. Alternatively, or in combination, one or more capacitors in the second set of capacitors may be formed on a surface of one or several semiconductor integrated circuit dies using post processing techniques, and/or one or more capacitors in the second set of capacitors may be one or more discrete capacitors bonded to a conductor pattern of the semiconductor component.

Regarding the configuration of the nano-structure based capacitor, it should be understood that the first electrode may be conductively connected to the nanostructures, so that current can flow from the first electrode to the nanostructures.

The present aspect of the invention is based upon the realization that the desired improved power distribution in the electronic system can be achieved through the inclusion in the power distribution network of discrete capacitors with improved properties, including one or several of a higher capacitance per unit area, a lower component height, a reduced equivalent series inductance (ESL), a capacitance value that is not reduced when a DC-bias is applied across the capacitor, etc., and that such properties may be achieved by nano-structure based discrete capacitors.

At least one capacitor in the first set of capacitors may advantageously exhibit an equivalent series inductance (ESL) of less than 100 pH within a range between the self-resonance frequency (SRF) and 1000 times the SRF of the capacitor.

In order to achieve such a low ESL across this frequency range, the inventors have found that it may be beneficial to tailor, using per se known techniques, the nano-structures in the discrete nano-structure based capacitor(s) to have certain dimensions, and to configure the discrete nano-structure based capacitor(s) to have a certain aspect ratio.

According to one advantageous embodiment, the average length of the nanostructures in the discrete nano-structure based capacitor(s) may be 0.1 μm to 100 μm, the average diameter of the nanostructures in the discrete nano-structure based capacitor(s) may be 1 nm to 150 nm, and the ratio between the average length and the average diameter may be at least 2:1, that is, the average length may be at least two times the average diameter.

According to another advantageous embodiment, the average length of the nanostructures in the discrete nano-structure based capacitor(s) may be 0.1 μm to 100 μm, the average diameter of the nanostructures in the discrete nano-structure based capacitor(s) may be 1 nm to 75 nm, and the ratio between the average length and the average diameter may be at least 10:1, that is, the average length may be at least ten times the average diameter.

In addition, each discrete nanostructure capacitor may advantageously have a rectangular footprint with a first long side and a second long side and a first short side and a second short side, wherein the first connecting structure may be provided along the first long side and the second connecting structure may be provided along the second long side.

The long sides of each discrete nanostructure capacitor may be at least two times as long as the short sides of the discrete nanostructure capacitor.

Furthermore, the first connecting structure may extend along at least one half of the length of the first long side and the second connecting structure may extend along at least one half of the length of the second long side.

Advantageously, for an even lower ESL in particular for higher frequencies, the first connecting structure may extend along at least 80% of the length of the first long side and the second connecting structure may extend along at least 80% of the length of the second long side.

Advantageously, for an even lower ESL in particular for higher frequencies, both the first connecting structure and the second connecting structure may have several alternative terminals or contact points at the periphery of the component. It may be a multiterminal component device.

Each capacitor in the first set of capacitors may advantageously exhibit an unchanged or increased capacitance when subjected to a DC voltage bias, as compared to its capacitance in an unbiased state.

To this end, the present inventors have found that the dielectric material separating each nanostructure in the first plurality of nanostructures from the second electrode may advantageously be a non-ferroelectric dielectric.

Through the further improved power distribution network (PDN) achievable through aspects of the present invention, more compact and/or higher performance (higher switching frequency) electronic systems can be provided.

According to various embodiments, the conductive nanostructures in the first plurality of conductive nanostructures may be vertical nanostructures grown from the first electrode layer. The use of grown nanostructures allows extensive tailoring of the properties of the nanostructures. For instance, the growth conditions may be selected to achieve a morphology giving a large surface area of each nanostructure, which may in turn increase the energy storage capacity of the nanostructure energy storage device.

The nanostructures may be selected from one of nanowire, nano-horns, nanotube, nano-walls, crystalline nanostructures, or amorphous nanostructures.

The nanostructures may advantageously be carbon nanostructures, such as carbon nanofibers, carbon nanotubes or carbide-derived carbon nanostructures.

According to embodiments, the dielectric material may advantageously be arranged as a conformal coating on each nanostructure in the first plurality of conductive nanostructures.

According to embodiments, the second electrode may cover the dielectric material.

According to various embodiments, moreover, the nanostructure energy storage device may further comprise a second plurality of conductive nanostructures embedded in the dielectric material.

In such embodiments, the second electrode may be conductively connected to each nanostructure in the second plurality of nanostructures.

In some embodiments, each nanostructure in the second plurality of conductive nanostructures may advantageously be grown from the second electrode.

The second electrode, or a portion of the second electrode, may instead be connected to the tip of nanostructures in the second plurality of nanostructures. In such embodiments, the nanostructures may be grown, embedded in the dielectric material, and the tips of the nanostructures then be exposed by removal of dielectric material, for example through dry or wet etching or polishing.

According to further embodiments, the first electrode, or a portion of the first electrode, may also be connected to the tip of nanostructures in the first plurality of nanostructures. In such embodiments, the nanostructures may be grown, embedded in the dielectric material, and the tips of the nanostructures then be exposed by removal of dielectric material, for example through dry or wet etching or polishing. Accordingly, both the first electrode and the second electrode may be provided after growth of the nanostructures.

The dielectric material in the nano-structure based capacitor(s) provides for energy storage by preventing electrical conduction from the conductive nanostructures in the first plurality of nanostructures to the second electrode. Hereby, energy can be stored through accumulation of charge at the nanostructure—dielectric interface. The dielectric may advantageously be a so-called high-k dielectric. The high k-dielectric materials e.g. be HfOx, HfAlOx, TiOx, TaOx, NiOx, MoOx, CuOx, PZT, BaTiOx, or other well-known high k dielectrics. Alternatively, the dielectric can be polymer based e.g. polypropylene, polystyrene, poly(p-xylylene), parylene, PBO etc. Other well-known dielectric materials, such as SiOx or SiNx, etc may also be used. The dielectric material or materials maybe deposited via CVD, thermal processes, ALD or spin coating or spray coating or any other suitable method used in the industry.

According to embodiments, each capacitor in a subset of the first set of capacitors may be arranged between the substrate and the semiconductor component. This arrangement of one or several capacitors in the first set of capacitors may reduce the length of the conductive path between the active circuitry of the semiconductor component and the capacitor(s), which, in turn, reduces the inductance in that part of the PDN. Furthermore, valuable substrate surface space may be made available, allowing for a more compact electronic system.

According to a third aspect of the present invention, it is provided an electronic system comprising: a substrate with a substrate conductor pattern and substrate pads included in the substrate conductor pattern; a semiconductor component with active circuitry, and component pads coupled to the active circuitry, the component pads being connected to the substrate pads; a power source interface for receiving power from a power source, the power source interface being connected to the substrate conductor pattern; and a power distribution network for distributing power from the power source interface to the active circuitry of the semiconductor component, the power distribution network including: a power grid portion of the substrate conductor pattern; a first set of capacitors bonded to the power grid portion of the substrate conductor pattern; and a second set of capacitors integrated in the semiconductor component, wherein each capacitor in the first set of capacitors is a discrete capacitor component exhibiting an equivalent series inductance of less than 100 pH for every frequency within a frequency range between the self-resonance frequency (SRF) and 1000 times the SRF of the capacitor component.

The present aspect of the invention is based upon the realization that the desired improved power distribution in the electronic system can be achieved through the inclusion in the power distribution network of discrete capacitors with improved properties, including one or several of a higher capacitance per surface area, a lower component height, a reduced equivalent series inductance (ESL), a capacitance value that is not reduced when a DC-bias is applied across the capacitor, etc.

The exceptionally low ESL of each capacitor in the first set of capacitors provides in a facilitated electrical design/impedance optimization of the PDN.

According to another aspect, each capacitor in the first set of capacitors may be a discrete capacitor component exhibiting an unchanged or increased capacitance when subjected to a DC voltage bias, as compared to its capacitance in an unbiased state.

Advantageously, furthermore, each capacitor in the first set of capacitors may be a discrete capacitor component exhibiting a capacitance per component footprint area of more than 5000 nF/mm².

According to embodiments, each capacitor in the first set of capacitors may be a discrete nano-structure based capacitor, comprising: at least a first plurality of electrically conductive nanostructures; a dielectric material embedding each nanostructure in the first plurality of conductive nanostructures; a first electrode conductively connected to each nanostructure in the first plurality of nanostructures; a second electrode separated from each nanostructure in the first plurality of nanostructures by the dielectric material, a first connecting structure conductively connected to the first electrode, the first connecting structure being bonded to the power grid portion of the substrate conductor pattern; and a second connecting structure conductively connected to the second electrode, the second connecting structure being bonded to the power grid portion of the substrate conductor pattern.

Further improved power distribution in the electronic system can be achieved through the inclusion in the power distribution network of discrete nano-structure based capacitors providing improved properties, including one or several of a higher capacitance per surface area, a lower component height, a reduced equivalent series inductance (ESL), a capacitance value that is not reduced when a DC-bias is applied across the capacitor, etc.

According to various embodiments, the conductive nanostructures in the first plurality of conductive nanostructures may be vertical nanostructures grown from the first electrode layer. The use of grown nanostructures allows extensive tailoring of the properties of the nanostructures. For instance, the growth conditions may be selected to achieve a morphology giving a large surface area of each nanostructure, which may in turn increase the energy storage capacity of the nanostructure energy storage device.

The nanostructures may be selected from one of nanowire, nano-horns, nanotube, nano-walls, crystalline nanostructures, or amorphous nanostructures.

The nanostructures may advantageously be carbon nanostructures, such as carbon nanofibers, carbon nanotubes or carbide-derived carbon nanostructures.

According to embodiments, the dielectric material may advantageously be arranged as a conformal coating on each nanostructure in the first plurality of conductive nanostructures.

According to embodiments, the second electrode may cover the dielectric material.

According to various embodiments, moreover, the nanostructure energy storage device may further comprise a second plurality of conductive nanostructures embedded in the dielectric material.

In such embodiments, the second electrode may be conductively connected to each nanostructure in the second plurality of nanostructures.

In some embodiments, each nanostructure in the second plurality of conductive nanostructures may advantageously be grown from the second electrode.

The second electrode, or a portion of the second electrode, may instead be connected to the tip of nanostructures in the second plurality of nanostructures. In such embodiments, the nanostructures may be grown, embedded in the dielectric material, and the tips of the nanostructures then be exposed by removal of dielectric material, for example through dry or wet etching or polishing.

According to further embodiments, the first electrode, or a portion of the first electrode, may also be connected to the tip of nanostructures in the first plurality of nanostructures. In such embodiments, the nanostructures may be grown, embedded in the dielectric material, and the tips of the nanostructures then be exposed by removal of dielectric material, for example through dry or wet etching or polishing. Accordingly, both the first electrode and the second electrode may be provided after growth of the nanostructures.

The dielectric material in the nano-structure based capacitor(s) provides for energy storage by preventing electrical conduction from the conductive nanostructures in the first plurality of nanostructures to the second electrode. Hereby, energy can be stored through accumulation of charge at the nanostructure—dielectric interface. The dielectric may advantageously be a so-called high-k dielectric. The high k-dielectric materials e.g. be HfOx, TiOx, TaOx, NiOx, MoOx, CuOx or other well-known high k dielectrics. Alternatively, the dielectric can be polymer based e.g. polypropylene, polystyrene, poly(p-xylylene), parylene etc. Other well-known dielectric materials, such as SiOx or SiNx, etc may also be used. The dielectric material or materials maybe deposited via CVD, thermal processes, ALD or spin coating or spray coating or any other suitable method used in the industry.

According to embodiments, the power distribution network may further comprise a third set of capacitors bonded to the component carrier conductor pattern.

At least one capacitor in the third set of capacitors may be a discrete capacitor component having a component thickness being less than 100 μm and a capacitance per component footprint area of more than 1000 nF/mm².

Through this combination of properties, the electrical design/impedance optimization of the PDN may be facilitated. The exceptionally small component thickness enables arrangement of one or more capacitors in the third set of capacitors between the substrate and the semiconductor component even with state-of-the-art, low-profile bonding solutions for bonding the semiconductor component to the substrate.

### BRIEF DESCRIPTION OF THE DRAWINGS

These and other aspects of the present invention will now be described in more detail, with reference to the appended drawings showing an example embodiment of the invention, wherein:

FIG. 1 schematically shows an example electronic device, here in the form of a mobile phone, including an electronic system according to embodiments of the present invention;

FIG. 2 is an enlarged view of a portion of the electronic system in FIG. 1;

FIG. 3 is a simplified illustration of an electronic system according to example embodiments of the present invention;

FIG. 4 is an equivalent circuit illustration of the PDN of the electronic system in FIG. 3;

FIG. 5 is an impedance diagram illustrating frequency characteristics relating to design aspects of a PDN;

FIG. 6 is a simplified schematic cross-section view of an electronic system according to example embodiments of the present invention;

FIG. 7 is a simplified cross-section view of the semiconductor component comprised in an electronic system according to other example embodiments of the present invention;

FIG. 8 is a schematic illustration of an exemplary capacitor component comprised in the PDN of the electronic system according to example embodiments of the present invention;

FIG. 9 is an illustration of an internal configuration of the capacitor component in FIG. 8; and

FIG. 10 is a schematic illustration of another exemplary capacitor component comprised in the PDN of the electronic system according to example embodiments of the present invention.

### DETAILED DESCRIPTION OF EXAMPLE EMBODIMENTS

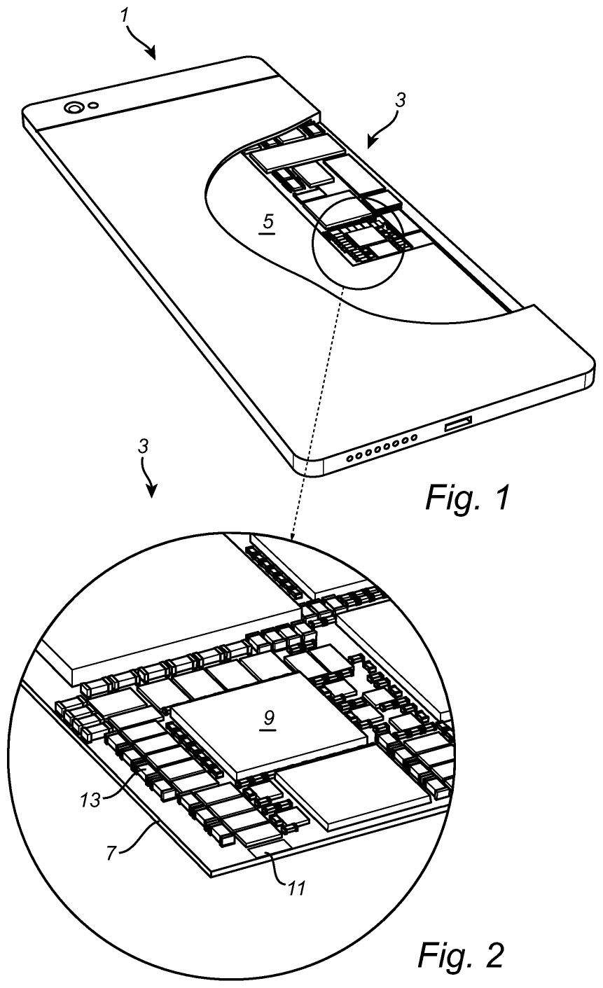

FIG. 1 schematically illustrates an electronic device according to embodiments of the present invention, here in the form of a mobile phone 1. In the simplified and schematic illustration in FIG. 1, it is indicated that the mobile phone, like most electronic devices, comprises an electronic system 3 controlling operation of the electronic device 1, and a power source, here in the form of a battery 5, for supplying power to the electronic system 3 and other parts of the electronic device 1.

Although the electronic device comprising the electronic system according to embodiments of the present invention has here been exemplified by a mobile phone 1, it should be understood that the electronic system according to various embodiments of the present invention may equally well be included in, and useful for, other types of electronic devices, such as, for example: an AR, VR, MR; an entertainment unit; a navigation device; a communications device; a fixed location data unit; a mobile location data unit; a global positioning system (GPS) device; a smart watch; a wearable computing device; a tablet; a server; a computer; a portable computer; a mobile computing device; a battery charger; a USB device; a desktop computer; a personal digital assistant (PDA); a monitor; a computer monitor; a television; a tuner; a radio; a satellite radio; a music player; a digital music player; a portable music player; a digital video player; an automobile; an electric vehicle; a vehicle component; avionics systems; a drone; and a multicopter.

In modern electronic devices, the electronic system 3 (in some applications also referred to as logic board) needs to be able to handle very heavy computational tasks, which may, for example, include advanced image processing etc. The electronic system 3 may also need to intermittently handle various diverse tasks simultaneously. Such tasks may involve processing carried out by different semiconductor components, that may be at least partly specialized for carried out their respective tasks.

FIG. 2 is an enlarged view of the electronic system 3 in FIG. 1, and schematically shows that the electronic system 3 comprises a substrate 7, a plurality of semiconductor components 9 (only one of the semiconductor components in FIG. 2 is indicated by a reference numeral, in order to avoid cluttering the drawing), and a power source interface 11 for receiving power from the power source 5. In order to efficiently and reliably distribute power from the power source interface 11 to the semiconductor components 9, the electronic system 3 further comprises a power distribution network (PDN). As is discussed and explained further above, there may be severe requirements on the PDN. The PDN should be capable of supplying sufficient power, at well-defined voltage levels, to all of the semiconductor components 9 of the electronic system 3 across a broad frequency range. For example, different semiconductor components 9 may exhibit sudden variations in the required power. The PDN should be capable of accommodating this without excessive variations in the supply voltage and without disturbing the supply of power to other semiconductor components. Designing and dimensioning the PDN is therefore a challenging task facing the team developing the electronic system 3. A successful PDN may require careful design of the substrate 7, the semiconductor components 9, as well as purposeful selection and arrangement of a large number of capacitor components 13 (again, only one of the capacitors included in the PDN is indicated by a reference numeral in FIG. 2).

Embodiments of the present invention enable the design of PDNs in electronic systems with less substrate space occupied by capacitors. This in turn provides for more compact electronic systems, which may allow for electronic devices with smaller dimensions and/or improved performance. For example, a larger battery may be accommodated for given overall dimensions of an electronic device such as a mobile phone 1. Smaller physical dimensions of an electronic system may in itself contribute to facilitate the design and configuration of the PDN for the electronic system, due to the reduced inductances resulting from shorter conductor lengths.

Moreover, the disclosed subject matter provides novel means for a circuit designer to meet power integrity guidelines set by end users, such as manufacturers of a given device (e.g., a mobile phone, computer etc.).

In various example embodiments, according to the present invention, a power distribution/delivery network (PDN) is provided comprising substantially lower volumetric discrete capacitor components between the power source and ground rail and between the power source and the active circuitry (in semiconductor components) in the system in close proximity of the actual demand. Hereby, a minimal loop inductance can be achieved and the corresponding voltage drop can be minimized.

Embodiments of the present invention can fulfil the requirement of (a) very high electrostatic or electrochemical capacitance value per unit area/volume, (b) low profile in 2D and Z direction, (c) surface mount compatible and suitable for 2D, 2.5D and 3D packaging/assembly/embedded technologies, (d) easy to design form factor, (e) Stable and robust performance against temperature and applied voltages, (f) low equivalent series inductance (ESL), (g) longer life time or enhanced life cycle without capacitive degradation, (h) low loop inductance, and (i) cost effective.

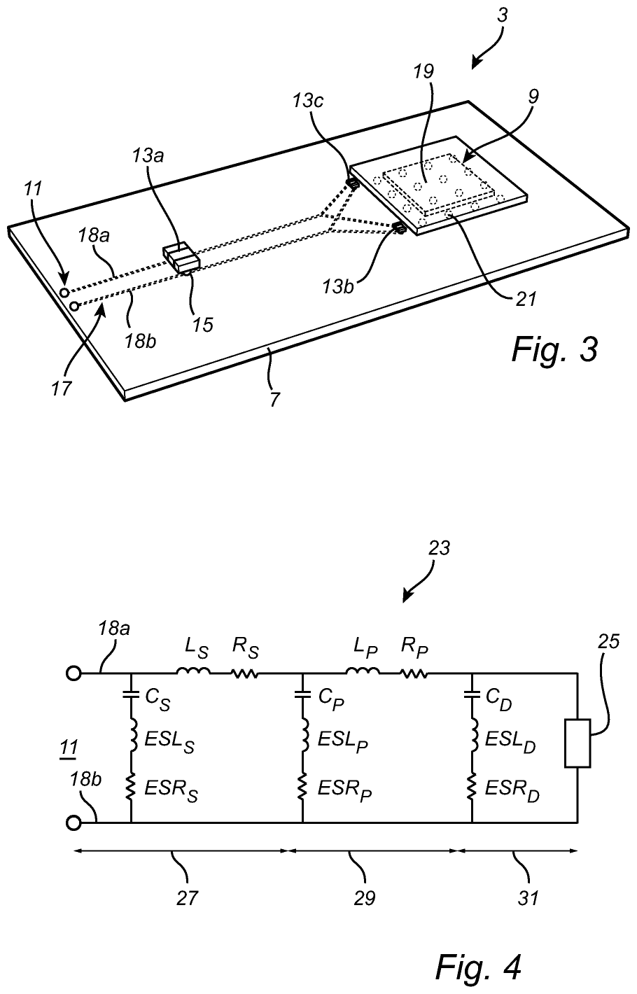

Various aspects and embodiments of the present invention will now be described in greater detail with reference initially to FIG. 3, which is a simplified illustration of an electronic system according to example embodiments of the present invention.

As is schematically illustrated in FIG. 3, the electronic system 3 comprises a substrate 7, a semiconductor component 9, a power source interface 11, and a first set of capacitors 13a-c. The substrate 7 has a substrate conductor pattern with substrate pads 15 (only one of the substrate pads is indicated by a reference numeral in FIG. 3). The substrate conductor pattern includes a power grid portion 17, which is a portion of the conductor pattern that is used for distributing power from the power source interface 11 to the semiconductor components 9 comprised in the electronic system 3. As is schematically indicated in FIG. 3, the power grid portion 17 includes at least a ground line 18a and a power line 18b. It should be noted that the power grid portion 17 of a more complex PDN, such as that required for the electronic system 3 in FIG. 2 would typically include several ground lines and several power lines, which may be arranged in different layers of the substrate. The semiconductor component 9 has active circuitry 19 and component pads 21, which are connected to corresponding substrate pads 15. In FIG. 3, the active circuitry is schematically indicated as comprised in a semiconductor die 19 inside a package. It should be noted, however, that the semiconductor component 9 need not necessarily be a packaged semiconductor component, but may be constituted by a naked semiconductor die, or by a semiconductor die provided with a redistribution layer (RDL) etc.

The electronic system 3 in FIG. 3 includes a PDN for distributing power from the power source interface 11 to the active circuitry of the semiconductor component 9. In the example configuration in FIG. 3, the PDN includes the power grid portion 17 of the substrate conductor pattern, a first set of capacitors 13a-c bonded to the power grid portion 17 of the substrate conductor pattern, a second set of capacitors integrated in the semiconductor component 9 (not shown/visible in FIG. 3), and a power distribution interface between the power grid portion 17 of the substrate conductor pattern and the semiconductor die 19. In the example configuration of FIG. 3, this power distribution interface may include connecting structures (such as bumps or pillars etc) bonded to the power grid portion 17 of the substrate conductor pattern, and any structures electrically connecting these connecting structures with the semiconductor die 19.

Regarding bonding of the capacitors to the substrate conductor pattern, or any other conductor pattern mentioned in this description, it should be understood that the bonding is an electrical and mechanical connection that can be achieved through, for example, metal to metal bonding, compression bonding, solder bonding, with or without underfill FC bonding, ACF film bonding, ultrasonic bonding, or a combination thereof, or any other bonding used by the industry.

Furthermore, the first set of capacitors may include a single capacitor, or a may include two or more capacitors electrically coupled in parallel or in series with one another. According to the various embodiments of the present invention, the capacitors can be tailored to appropriate characteristics, for example, level of energy storage, form factor of the discrete components (in x, y, and z), effective equivalent resistance and effective equivalent inductance to comply with the circuit need to suppress noise signals from entering into the active circuitry of the semiconductor components 9. Even though it is not explicitly shown in the figures, embodiments may contain other noise filtering elements such as ferrite beads.

By being able to provide the capacitor components in close proximity of the need, a more reliable, shorter current loop can be created, which in turn provides for reduced transient noise entering into the active circuitry of the semiconductor components 9.

The PDN of the electronic system 3 may suitably be represented by the simplified PDN RLC electrical equivalent model 23 in FIG. 4, distributing power from the power source interface 11 to the active circuitry 25 of the semiconductor component 9. As is schematically indicated by the line under the equivalent model 23, the simplified PDN representation comprises a first portion 27 electrically representing the power grid portion 17 of the substrate conductor pattern and the first set of capacitors 13a-c, a second portion 29 electrically representing the power distribution interface between the power grid portion 17 of the substrate conductor pattern and the semiconductor die 19, and a third portion 31, being a simplified electrical representation of power distribution structures of the semiconductor die 19.

As is schematically indicated in FIG. 4, the first portion 27 of the PDN electrical equivalent model 23 includes a parallel branch with a capacitance C_{S}, an equivalent series inductance ESL_{S} and an equivalent series resistance ESR_{S}, and a series branch with an inductance L_{S}, and a resistance R_{S}. The second portion 29 of the PDN electrical equivalent model 23 includes a parallel branch with a capacitance C_{P}, an equivalent series inductance ESL_{P} and an equivalent series resistance ESR_{P}, and a series branch with an inductance L_{P}, and a resistance R_{P}. The third portion 31 of the PDN electrical equivalent model 23 includes a parallel branch with a capacitance C_{D}, an equivalent series inductance ESL_{D} and an equivalent series resistance ESR_{D}. Based on the properties of the equivalent circuit elements in the PDN electrical equivalent model 23, the active circuitry 25 and the power source interface 11 will experience a total frequency dependent impedance Z(f).

When designing the PDN of an electronic system 3, a target impedance Z_{target} is generally defined, which will almost certainly ensure that the power supply will not exceed a specified voltage tolerance with a given transient current. The designers of the PDN then aim to keep the impedance Z(f) of the PDN below the target impedance Z_{target} for frequencies up to the highest switching frequency of the electronic system 3.

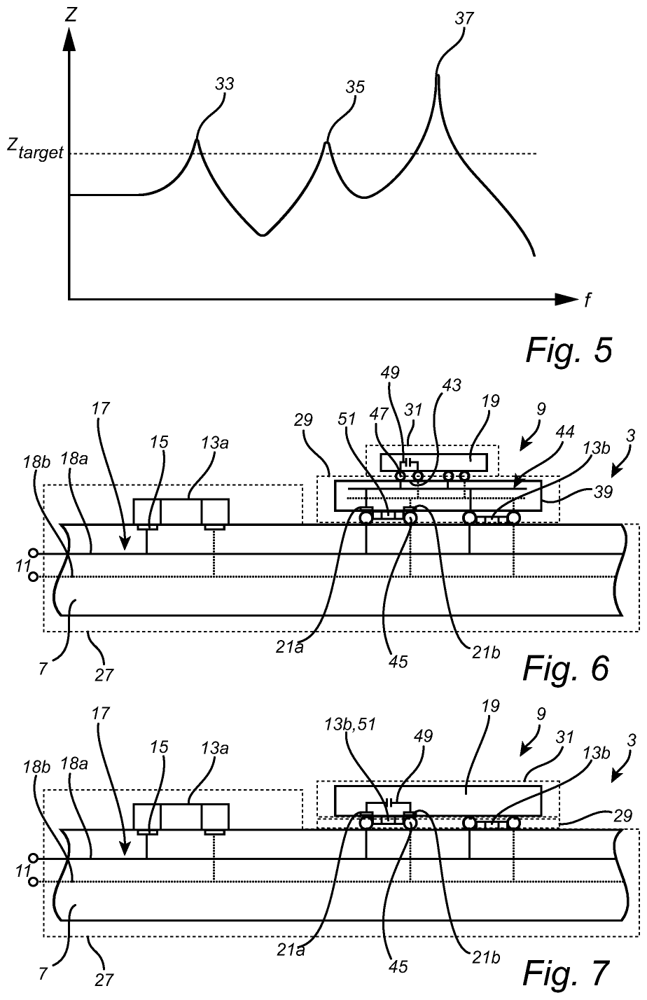

A schematic representation of the PDN impedance Z(f) as a function of frequency f is shown in the diagram in FIG. 5. In this diagram, there is a low-frequency impedance peak 33, a medium-frequency impedance peak 35 and a high-frequency impedance peak 37. The main tools available to the designers of the PDN to strive to keep the PDN impedance Z(f) below the target impedance Z_{target} from a low frequency to a sufficiently high frequency are different for the different frequency ranges. To reduce the low-frequency impedance peak 33, the configuration of the substrate 7 as well as the properties and arrangement of the capacitors 13a-c in the first set of capacitors may be effective to optimize the above-mentioned equivalent electrical property values in the first portion 27 of the PDN electrical equivalent model 23. To reduce the medium-frequency impedance peak 35, the configuration of the connecting structures between the power grid portion 17 of the substrate conductor pattern and the semiconductor die 19 may be effective to optimize the above-mentioned equivalent electrical property values in the second portion 29 of the PDN electrical equivalent model 23. To reduce the high frequency impedance peak 37, if required, options may be limited in the circuit design constrained by the stringent physical space of a conventional semiconductor die 19.

In the following, it will be explained how various aspects and embodiments of the present invention provide new tools for PDN designers to achieve PDNs with improved properties, that may also allow for more compact and more cost-efficient electronic systems including such PDNs.

For illustrative purposes, a simplified schematic cross-section view of an electronic system 3 according to embodiments of the invention is provided in FIG. 6.

In this example configuration, the first set of capacitors bonded to the power grid portion 17 of the substrate conductor pattern includes a first capacitor 13a arranged relatively close to the power supply interface 11, and a second capacitor 13b arranged between the substrate 7 and the semiconductor component 9.

Furthermore, the semiconductor component 9 comprises a component carrier 39 with the component pads 21, die bonding pads 43, and a component carrier conductor pattern connecting the component pads 21 and the die bonding pads 43. The component carrier conductor pattern includes a power grid portion 44. As is schematically shown in FIG. 6, the component pads 21 are connected to substrate pads using first connecting structures 45, and the die bonding pads 43 are connected to die pads of the semiconductor die 19 using second connecting structures 47. Also schematically indicated in FIG. 6 are a first capacitor 49 realized by conductive structures comprised in the semiconductor component (here in the semiconductor die 19) and a second capacitor 51 arranged between the substrate 7 and the semiconductor component 9. In the example configuration of FIG. 6, the above-mentioned first capacitor 49 is coupled to a first component pad 21a and a second component pad 21b of the semiconductor component 9, and the second capacitor 51 is coupled to the first component pad 21a and the second component pad 21b. In FIG. 6, the component carrier 39 is schematically illustrated as an interposer. However, the component carrier 39 is not limited to being an interposer, but could be any other suitable component carrier, such as, for example a lead-frame.

In FIG. 6, portions of the electronic system 3 corresponding to the first 27, second 29 and third 31 portions of the PDN electrical equivalent model 23 in FIG. 4 are schematically indicated. The low-frequency first portion 27 of the PDN includes the power grid portion 17 of the substrate conductor pattern, and the above-mentioned first capacitor 13a in the first set of capacitors. The medium-frequency second portion 29 of the PDN here includes the above-mentioned second capacitor 13b in the first set of capacitors, the above-mentioned power grid portion 44 of the component carrier conductor pattern, the above-mentioned second capacitor 51, and the above-mentioned first 45 and second 47 connecting structures. The high-frequency third portion 31 of the PDN here includes front end of line (FEOL) and back end of line (BEOL) structures of the semiconductor die 19, including the above-mentioned first capacitor 49. As will be explained further below, at least the above-mentioned second capacitor 51 and structures connecting the first capacitor 49 and the second capacitor 51 may be considered to be included in the high-frequency third portion 31 of the PDN, depending on the configuration and properties of the second capacitor 51 and the connecting structures.

FIG. 7 is a simplified cross-section view of the semiconductor component comprised in an electronic system 3 according to other example embodiments of the present invention. The electronic system 3 in FIG. 7 mainly differs from that in FIG. 6 in that the semiconductor component 9 does not include a component carrier, so that the semiconductor die 19 is directly coupled to the substrate conductor pattern of the substrate 17.

In FIG. 7, like in FIG. 6, portions of the electronic system 3 corresponding to the first 27, second 29 and third 31 portions of the PDN electrical equivalent model 23 in FIG. 4 are schematically indicated. In the example embodiments of FIG. 7, the low-frequency first portion 27 of the PDN includes the power grid portion 17 of the substrate conductor pattern, and the first capacitor 13a in the first set of capacitors. The medium-frequency second portion 29 of the PDN here includes the second capacitor 13b in the first set of capacitors, which also corresponds to the above-mentioned second capacitor 51, and connecting structures 45 between the substrate 7 and the semiconductor component 9. The high-frequency third portion 31 of the PDN here includes front end of line (FEOL) and back end of line (BEOL) structures of the semiconductor die 19, including the above-mentioned first capacitor 49. As will be explained further below, at least the above-mentioned second capacitor 51 and structures connecting the first capacitor 49 and the second capacitor 51 may be considered to be included in the high-frequency third portion 31 of the PDN, depending on the configuration and properties of the second capacitor 51 and the connecting structures.

In embodiments, the electronic system 3 may be configured as a hybrid of the configuration in FIG. 6 and the configuration in FIG. 7. Accordingly, there may be a additional capacitor component connected between a pair of second connecting structures 47 in FIG. 6 that are also connected to the first capacitor 49.

Various aspects and embodiments of the present invention can be said to have different starting points for providing for improvements of the PDN of the electronic system 3.

According to one aspect, the provision of the above-mentioned second capacitor 51 arranged between the substrate 7 and the semiconductor component 9 and coupled to the first component pad 21a and the second component pad 21b of the semiconductor component 9 may considerably reduce the equivalent series inductance ESL_{P} in the medium-frequency second portion 29 of the PDN and possibly also reduce the equivalent series inductance ESL_{D} in the high-frequency third portion 31 of the PDN, depending on the dimensions of the conductors between the first capacitor 49 and the second capacitor 51, as well as on the electrical properties of the second capacitor 51. This may be particularly useful for reducing the second peak 35 and the third peak 37 in the diagram in FIG. 5, without utilizing any substrate area between semiconductor components 9.

For convenient implementation in the electronic system 3, the second capacitor 51 may advantageously be a discrete capacitor, as is schematically indicated in the drawings. Furthermore, to enable arrangement of the second capacitor 51 between the substrate 7 and the semiconductor component 9 in the manner indicated in the simplified illustrations in FIG. 6 and FIG. 7, the thickness of the discrete capacitor component 51 may advantageously be less than 100 μm. Furthermore, the discrete capacitor component 51 may advantageously have a capacitance per component footprint area of more than 1000 nF/mm². According to embodiments of the present invention, a discrete capacitor component 51 exhibiting such beneficial properties may be a nano-structure based capacitor component. Example configurations of such a nano-structure based capacitor component will be described in detail further below.

According to another aspect, properties of the low-frequency first portion 27 of the PDN can be improved, potentially using a reduced number of capacitors 13a in the first set of capacitors, by providing each capacitor 13a in the first set of capacitors as a discrete capacitor component exhibiting an equivalent series inductance of less than 100 pH across the frequency range from the self-resonance frequency to 1000 times the self-resonance frequency of the capacitor. Hereby, the equivalent series inductance ESL_{S} in the low-frequency first portion 27 of the PDN can be reduced. This may be particularly useful for reducing the first peak 33 in the diagram in FIG. 5, while using less substrate area between semiconductor components 9. This may particularly be the case when each capacitor component 13a in the first set of capacitors also exhibits a capacitance per component footprint area of more than 5000 nF/mm². According to embodiments of the present invention, a discrete capacitor component 13a exhibiting such beneficial properties may be a nanostructure-based capacitor component. Example configurations of such a nanostructure-based capacitor component will be described in detail further below. It should be noted that the nanostructures in any of the nanostructure-based capacitor components comprised in the electronic system 3 according to embodiments of the present invention may be selected from one of nanowire, nano-horns, nanotube, nano-walls, crystalline nanostructures, amorphous nanostructures, Si nanowires, metal nanowires, or any other suitable elongated functionalized or non-functionalized nanostructures. Furthermore, when “electrically conductive” or “conductive” nanostructures are referred to in the present application, it should be understood that this wording encompasses nanostructures that are inherently conductive, as well as electrically insulating nanostructures that are conformally coated by a thin layer of conductive material, such as a metallic material.

In various examples of embodiments of the present invention, utilized discrete capacitors may have a capacitance ranging between 40 and 1000 nF and an equivalent series resistance of below 150 mOhms. These capacitors may have self-resonance frequencies ranging between 50 MHz and 400 MHz.

In various examples of embodiments of the present invention, utilized discrete capacitors may have a capacitance ranging between 1 and 10 nF and an equivalent series resistance of below 50 mOhms. These capacitors may have self-resonance frequencies ranging between 100 MHz and 2000 MHz.

In various example embodiments, the equivalent series inductance (ESL) of one or more capacitors may advantageously be less than 25 pH, and even more advantageously less than 10 pH, for every frequency within a frequency range between the self-resonance frequency (SRF) and 1000 times the SRF of the capacitor.

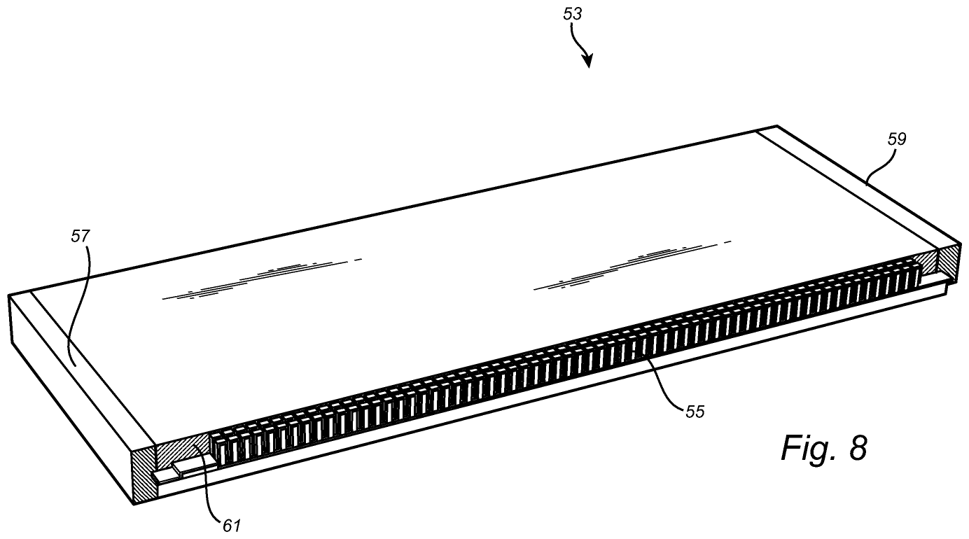

FIG. 8 is a schematic illustration of an exemplary nanostructure-based capacitor component 53, that may be comprised in the PDN of the electronic system 3 according to example embodiments of the present invention. This capacitor component 53 is a discrete capacitor component, comprising a MIM-arrangement 55, a first connecting structure, here in the form of a first end connector 57, a second connecting structure, here in the form of a second end connector 59, and an electrically insulating encapsulation material 61, at least partly embedding the MIM-arrangement 55. As can be seen in FIG. 8, the electrically insulating encapsulation material 61 at least partly forms an outer boundary surface of the energy storage component. The first 57 and second 59 connecting structures also at least partly form the outer boundary surface of the energy storage component. In FIG. 8, the first 57 and second 59 connecting structures are illustrated as being arranged on the short sides of the rectangular component 53. In embodiments, the first 57 and second 59 connecting structures may instead be arranged on the long sides of the component. Such a configuration may provide for a reduced series inductance of the component.

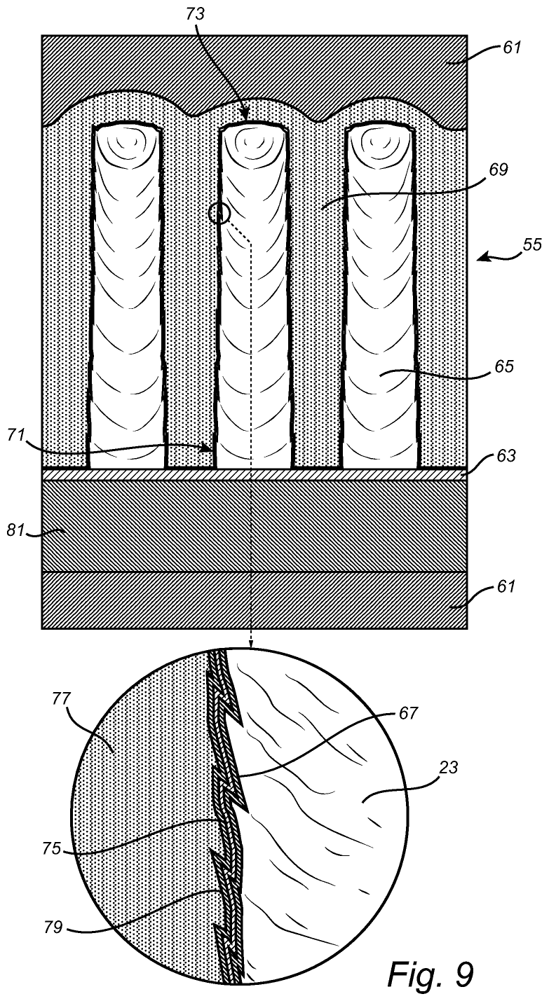

An example configuration of the MIM-arrangement 55 will now be described with reference to FIG. 9. As is schematically shown in FIG. 9, the MIM-arrangement 55 comprises a first electrode layer 63 on a MIM-arrangement substrate 81, a plurality of conductive nanostructures 65 vertically grown from the first electrode layer 63, a solid dielectric material layer 67 conformally coating each nanostructure 65 in the plurality of conductive nanostructures and the first electrode layer 63 not covered by the conductive nanostructures 65, and a second electrode layer 69 covering the solid dielectric material layer 67. As can be seen in FIG. 9, the second electrode layer 69 completely fills a space between adjacent nanostructures more than halfway between a base 71 and a top 73 of the nanostructures 65. In the exemplary MIM-arrangement 55 in FIG. 9, the second electrode layer 69 completely fills the space between adjacent nanostructures 65, all the way from the base 71 to the top 73, and beyond.

As can be seen in the enlarged view of the boundary between nanostructure 65 and second electrode layer 69 in FIG. 9, the second electrode layer 69 comprises a first sublayer 75 conformally coating the solid dielectric material layer 67, a second sublayer 77, and a third sublayer 79 between the first sublayer 75 and the second sublayer 77.

Moreover, additional sub layer(s) for example as metal diffusion barrier not shown in the figure may conveniently be present in accordance with the present invention disclosure.

The dielectric material layer 67 may be a multi-layer structure, which may include sub-layers of different material compositions.

According to embodiments of the invention, the MIM-arrangement 55 may comprise a solid dielectric and an electrolyte in a layered configuration. In such embodiments, the component 53 may be seen as a hybrid between a capacitor-type (electrostatic) and a battery-type (electrochemical) energy storage device. This configuration may provide for a higher energy density and power density than a pure capacitor component and faster charging than pure battery component.

An example method a of manufacturing a discrete nanostructure-based capacitor component 53, including the exemplary MIM-arrangement 55 in FIG. 9, will now be described.

In a first step, there is provided a MIM-arrangement substrate 81. Various substrates may be used, for example, silicon, glass, stainless steel, ceramic, SiC, or any other suitable substrate materials found in the industry. The substrate can however be high temperature polymer such as polyimide. Advantageously, the MIM-arrangement substrate 81 may be an electrically insulating substrate.

In the subsequent step, a first electrode layer 63 is formed on the substrate 81. The first electrode layer 63 can be formed via physical vapor deposition (PVD), chemical vapor deposition (CVD), atomic layer deposition (ALD), or any other method used in the industry. In some implementations, the first electrode layer 63 may comprise one or more metals selected from: Cu, Ti, W, Mo, Co, Pt, Al, Au, Pd, Ni, Fe and silicide. In some implementations, the first electrode layer 63 may comprise one or more conducting alloys selected from: TiC, TiN, WN, and AlN. In some implementations, the first metal layer 63 may comprise one or more conducting polymers. In some implementations, the first electrode layer 63 may be metal oxide e.g. LiCoO₂, doped silicon. In some implementations, the first metal layer 63 may be the substrate itself e.g. Al/Cu/Ag foil etc.

In the next step, a catalyst layer may be provided on the first electrode layer 63. The catalyst can, for example, be nickel, iron, platinum, palladium, nickel-silicide, cobalt, molybdenum, Au or alloys thereof, or can be combined with other materials (e.g., silicon). The catalyst can be optional, as the technology described herein can also be applied in a catalyst-free growth process for nanostructures. Catalyst can also be deposited through spin coating of catalyst particles.

In some implementations, a layer of catalyst is used to grow the nanostructures as well as to be used as connecting electrodes. In such implementations, the catalyst can be a thick layer of nickel, iron, platinum, palladium, nickel-silicide, cobalt, molybdenum, Au or alloys thereof, or can be combined with other materials from periodic table. The catalyst layer (not shown in FIG. 9), may be provided as a uniform layer or as a patterned layer. The formation of a patterned layer of course requires more processing than an unpatterned layer, but may provide for a higher or lower, and a more regular density of nanostructures 65, which may in turn provide for a higher capacitance of the finished nanostructure-based capacitor components 53 or more control over the absolute capacitance values per capacitor device if more than one capacitor is embedded in capacitor component 53.

Nanostructures 65 are then grown from the catalyst layer. Use of vertically grown nanostructures allows extensive tailoring of the properties of the nanostructures. For instance, the growth conditions may be selected to achieve a morphology giving a large surface area of each nanostructure, which may in turn increase the charge storing capacitance or capacitance per 2D footprint. As an alternative to CNF, the nanostructures may be metallic carbon nanotubes or carbide-derived carbon nanostructures, nanowires such as copper, aluminum, silver, silicide or other types of nanowires with conductive properties. Advantageously, the catalyst material, and growth gases etc may be selected in, per se, known ways to achieve so-called tip growth of the nanostructures 65, which may result in catalyst layer material at the tips 73 of the nanostructures 65. Following the growth of the vertically aligned conductive nanostructures 65, the nanostructures 65 and the first electrode layer 63 may optionally be conformally coated by a metal layer, primarily for improved adhesion between the nanostructures 65 and the conduction controlling material.

Following the growth of the vertically aligned conductive nanostructures 65, the nanostructures 65, and the portions of the first electrode layer 63 left uncovered by the nanostructures 65, may be conformally coated by a layer 67 of a solid dielectric material. The solid dielectric material layer 67 may advantageously be made of a so-called high-k dielectric. The high k-dielectric materials may e.g. be HfOx, TiOx, TaOx or other well-known high k dielectrics. Alternatively, the dielectric can be polymer based e.g. polypropylene, polystyrene, poly(p-xylylene), parylene etc. Other well-known dielectric materials, such as SiOx or SiNx, etc may also be used as the dielectric layer. Any other suitable conduction controlling materials may appropriately be used. The dielectric materials may be deposited via CVD, thermal processes, atomic layer deposition (ALD) or spin coating or spray coating or any other suitable method used in the industry. In various embodiments it may be advantageous to use more than one dielectric layer or dissimilar dielectric materials with different dielectric constant or different thicknesses of dielectric materials to control the effective dielectric constant or influence the breakdown voltage or the combination of them to control the dielectric film properties. Advantageously, the solid dielectric material layer 67 is coated uniformly with atomic uniformity over the nanostructures 65 such that the dielectric layer covers the entirety of the nanostructures 65 so that the leakage current of the capacitor device is minimized. Another advantage of providing the solid dielectric layer 67 with atomic uniformity is that the solid dielectric layer 67 can conform to the extremely small surface irregularities of the conductive nanostructures 65, which may be introduced during growth of the nanostructures. This provides for an increased total electrode surface area of the MIM-arrangement 55, which in turn provides for a higher capacitance for a given component size.

Thereafter, an adhesion metal layer—the above-mentioned first sub-layer 75 of the second electrode layer 69—is conformally coated on the solid dielectric material layer 67. The adhesion metal layer 75 may advantageously be formed using ALD, and an example of a suitable material for the adhesion metal layer 75 may be Ti, or TiN.

On top of the adhesion metal layer 75, a so-called seed metal layer 79—the above-mentioned third sub-layer 79 of the second electrode layer 69—may optionally be formed. The seed metal layer 79 may be conformally coated on the adhesion metal layer 75. The seed metal layer 79 may, for example, be made of Al, Cu or any other suitable seed metal materials.

Following formation of the seed metal layer 79, the above-mentioned second sub-layer 77 is provided. This second sub-layer 77 of the second electrode layer 63 may, for example, be formed via chemical method such as electroplating, electroless plating or any other method known in the art. As is schematically indicated in FIG. 9, the second sub-layer 77 may advantageously fill the spaces between the nanostructures 65 to provide for improved structural robustness etc.

The first 57 and second 59 connecting structures, such as bumps, balls or pillars, may be formed using, per se, known techniques. Thereafter, insulating encapsulation material 61 is provided to at least partly embed the MIM-arrangement 55. Any known suitable encapsulant material can be used for the encapsulant layer, for example, silicone, epoxy, polyimide, BCB, resins, silica gel, epoxy underfill etc. In some aspect, silicone materials can be favorable if it fits with certain other IC packaging schemes. Encapsulant may be cured to form the encapsulation layer. In some aspect of the present invention, the encapsulant layer maybe a curable material so that the passive component can be attached through curing process. In some aspect, the dielectric constant of the encapsulant is different than the dielectric constant of the dielectric materials used in the MIM construction. In some aspects, lower dielectric constant of the encapsulant materials is preferred compared with the dielectric materials used in manufacturing the MIM capacitor. In some aspect, SiN, SiO or spin on glass can also be used as a encapsulant materials. The encapsulant layer can be spin coated and dried, deposited by CVD, or by any other method known in the art.

After this step, the substrate 81 may optionally be thinned down or completely removed, depending on the desired configuration of the finished capacitor component 53.

For the case where the substrate is the first electrode, this step is optional unless further thinning is necessary.

In the following step, the panels or wafers are singulated using known techniques to provide the discrete MIM-capacitor components 53.

Any of the previously described embodiments are suitable to be fabricated at a wafer level processes and panel level processes used in the industry. They may conveniently be referred to as wafer level processing and panel level processing respectively. In wafer level processing typically, a circular shaped substrate is used, size ranging from 2 inch to 12-inch wafers. In the panel level processing, the size is defined by the machine capacity and can be circular or rectangular or square ranging larger sizes typically but not limited to 12 to 100 inches. Panel level processing is typically used in producing smart televisions. Hence the size can be as the size of a television or larger. In an aspect for wafer level processes, at least one of the embodiments described above is processed at a wafer level in a semiconductor processing foundry. In another aspect, for panel level processes, at least one of the embodiments described above is processed using panel level processing. Depending on the design requirements, after processing, the wafer or panel is cut into smaller pieces utilizing standard dicing, plasma dicing or laser cutting. Such singulation process step can be configured through dicing or plasma dicing or laser cutting to tailor the shape and size of the discrete component formed according to the need.

The present invention is also contemplated to be compatible to be used in the roll to roll manufacturing technology. Roll to roll processing is a method of producing flexible and large-area electronic devices on a roll of plastic or metal foil. The method is also described as printing method. Substrate materials used in roll to roll printing are typically paper, plastic films or metal foils or stainless steel. The roll to roll method enables a much higher throughput than other methods like wafer level or panel levels and have much smaller carbon footprint and utilize less energy. Roll to roll processing is applied in numerous manufacturing fields such as flexible and large-area electronics devices, flexible solar panels, printed/flexible thin-film batteries, fibers and textiles, metal foil and sheet manufacturing, medical products, energy products in buildings, membranes and nanotechnology.

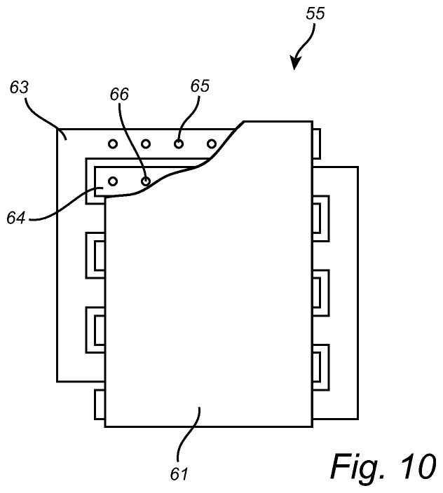

According to another example configuration of the MIM-arrangement 55 schematically illustrated in FIG. 10, there may be a second plurality of conductive nanostructures 66 embedded in the dielectric material 61. Each nanostructure 66 in the second plurality of conductive nanostructures may be vertically arranged on a second electrode layer 64, which may be formed in the same plane as the first electrode layer 63.

In embodiments of the present invention, the number of and/or the geometry or the combination thereof of nanostructures may be tuned or configured to control an effective self-resonance frequency (SRF) of the discrete capacitor component 53 including the nanostructures.

According to embodiments, the nanostructures may be configured to be substantially parallel to each other. Advantageously, the mutually parallel nanostructures may be arranged in a hexagonal unit cell configuration, which provides for an increased capacitance per unit area.

Alternatively, the nanostructures may be randomly oriented.

According to the embodiments, each capacitor in a subset of the capacitors may be designed and arranged to be effective for one of low-, medium- and high-frequency operation ranges with characteristic self-resonance frequencies (SRF) adapted therefore.

In embodiments, the number of and/or the geometry of the nanostructures may be configured to control an effective Q-value of the nanostructure-based capacitor component 53 to be less than 120.

One or more capacitor components comprised in the PDN of the electronic system 3 according to embodiments of the present invention may form at least a portion of a noise suppression filter.

Capacitor components may be connected in series with the semiconductor component 9.

According to the embodiments, the presence of any other types of capacitors including TSC, MLCC, Tantalum or LICC is not excluded, and such other types of capacitors may hence be provided as part of the structure to form the PDN network system without deviating from the scope of the present invention.

Moreover, the present invention disclosures anticipates that by implementing one or more of the various embodiments of the disclosed subject matter presented herein, a significant savings in both area (e.g., an X-Y footprint of a capacitor component) and volume (e.g., the area combined with a height of the capacitor component) on, for example, a PCB or on a die, can be realized. The savings in area and volume can assist greatly in meeting future generations of various form-factors and reduced cost/bill of materials.

The person skilled in the art realizes that the present invention by no means is limited to the preferred embodiments described above. On the contrary, many modifications and variations are possible within the scope of the appended claims.

In the claims, the word “comprising” does not exclude other elements or steps, and the indefinite article “a” or “an” does not exclude a plurality. A single processor or other unit may fulfill the functions of several items recited in the claims. The mere fact that certain measures are recited in mutually different dependent claims does not indicate that a combination of these measures cannot be used to advantage. Any reference signs in the claims should not be construed as limiting the scope.

1. An electronic system comprising:
a substrate with a substrate conductor pattern, the substrate having substrate pads included in the substrate conductor pattern;
a semiconductor component with active circuitry, and component pads coupled to the active circuitry of the semiconductor component, the component pads being connected to the substrate pads of the substrate;
a power source interface for receiving power from a power source, the power source interface being connected to the substrate conductor pattern; and
a power distribution network for distributing power from the power source interface to the active circuitry of the semiconductor component, the power distribution network including:
a first capacitor realized by conductive structures comprised in the semiconductor component, the first capacitor being coupled to a first component pad and a second component pad of the semiconductor component;
a second capacitor arranged between the substrate and the semiconductor component, the second capacitor being coupled to the first component pad and the second component pad of the component package; and
a power grid portion of the substrate conductor pattern.

2. The electronic system according to claim 1, wherein the second capacitor is a discrete capacitor component having a first connecting structure bonded to the first component pad and a second connecting structure bonded to the second component pad.

3. The electronic system according to claim 1, wherein the second capacitor is a discrete nano-structure based capacitor, comprising:
at least a first plurality of electrically conductive nanostructures;
a dielectric material embedding each nanostructure in the first plurality of conductive nano structures;
a first electrode conductively connected to each nanostructure in the first plurality of nano structures;
a second electrode separated from each nanostructure in the first plurality of nanostructures by the dielectric material,
a first connecting structure conductively connected to the first electrode, the first connecting structure being bonded to the first component pad; and
a second connecting structure conductively connected to the second electrode, the second connecting structure being bonded to the second component pad.

4. The electronic system according to claim 1, wherein:
the first capacitor has a capacitance less than 100 nF; and
the second capacitor is a discrete capacitor component having a component thickness being less than 100 μm, and a capacitance per component footprint area of more than 200 nF/mm².

5. The electronic system according to claim 1, wherein:
the semiconductor component comprises:
a semiconductor die comprising the active circuitry, and die pads coupled to the active circuitry; and
a component carrier comprising the component pads, die bonding pads, and a component carrier conductor pattern connecting the component pads and the die bonding pads, wherein the die bonding pads are connected to the die pads of the semiconductor die; and
the power distribution network further comprises a power grid portion of the component carrier conductor pattern.

6. The electronic system according to claim 1, wherein the power distribution network further comprises a set of capacitors bonded to the power grid portion of the substrate conductor pattern.

7. The electronic system according to claim 6, wherein each capacitor in the set of capacitors bonded to the power grid portion of the substrate conductor pattern is a discrete nano-structure based capacitor, comprising:
at least a first plurality of electrically conductive nanostructures;
a dielectric material embedding each nanostructure in the first plurality of conductive nano structures;
a first electrode conductively connected to each nanostructure in the first plurality of nano structures;
a second electrode separated from each nanostructure in the first plurality of nanostructures by the dielectric material,
a first connecting structure conductively connected to the first electrode, the first connecting structure being bonded to the power grid portion of the substrate conductor pattern; and
a second connecting structure conductively connected to the second electrode, the second connecting structure being bonded to the power grid portion of the substrate conductor pattern.

8. The electronic system according to claim 6, wherein each capacitor in the set of capacitors bonded to the power grid portion of the substrate conductor pattern is a discrete capacitor component exhibiting an equivalent series inductance of less than 100 pH for every frequency within a range between the self-resonance frequency (SRF) and 1000 times the SRF of the capacitor component.

9. The electronic system according to claim 6, wherein each capacitor in the set of capacitors bonded to the power grid portion of the substrate conductor pattern is a discrete capacitor component exhibiting an unchanged or increased capacitance when subjected to a DC voltage bias, as compared to its capacitance in an unbiased state.

10. The electronic system according to claim 6, wherein each capacitor in the set of capacitors is bonded to the power grid portion of the substrate conductor pattern by metal-to-metal bonding, compression bonding, solder bonding, with or without underfill FC bonding, ACF film bonding, ultrasonic bonding, or a combination thereof, or any other bonding used by the industry.

11. The electronic system according to claim 1, wherein the substrate is a printed circuit board (PCB), a substrate like PCB (SLP), or a silicon substrate or a substrate made of glass or ceramic or LTCC.

12. An electronic device comprising:
the electronic system according to claim 1; and
a power source coupled to the power source interface of the electronic system for providing power to the electronic system.

13. The electronic device according to claim 12, wherein the electronic device is one of a mobile phone; an entertainment unit; a navigation device; a communications device; a fixed location data unit; a mobile location data unit; a global positioning system (GPS) device; a smart watch; a wearable computing device; a tablet; a server; a computer; a portable computer; a mobile computing device; a battery charger; a USB device; a desktop computer; a personal digital assistant (PDA); a monitor; a computer monitor; a television; a tuner; a radio; a satellite radio; a music player; a digital music player; a portable music player; a digital video player; an automobile; an electric vehicle; a vehicle component; avionics systems; a drone; and a multicopter.
